(19) United States
(12) Patent Application Publication
(10) Pub. No.: US 2003/0003649 A1
(43) Pub. Date: Jan. 2, 2003

(54) Method for forming a capacitor of a semiconductor device

(76) Inventors: Dong-Su Park, Kyunggi-do (KR); Cheol-hwan Park, Seoul (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/184,706

(22) Filed: Jun. 28, 2002

(30) Foreign Application Priority Data
Jun. 29, 2001 (KR) 2001-38498

(51) Int. Cl. H01L 21/8242

(52) U.S. Cl. 438/239; 438/250

(57) ABSTRACT

A method for forming a metal MIS capacitor of a semiconductor device, in which a TiN layer forming an upper electrode is deposited by an atomic layer deposition (ALD) method using MO source at a low temperature, whereby the crystallization of TiN is minimized to prevent roughness of the surface, and Cl is not contained in the TiN layer to improve the leakage current characteristic.

### BACKGROUND OF THE DISCLOSURE

1. Field of the Disclosure

The disclosure relates to a method for forming a capacitor of a semiconductor device and, more particularly, to a method for forming a metal (MIS) capacitor of a semiconductor device, in which a TiN layer forming an upper electrode is deposited by an atomic layer deposition (ALD) method using an MO source in a low temperature, whereby crystallization of TiN is minimized to prevent roughness of the surface, and Cl is not contained in the TiN layer to improve the leakage current characteristic.

2. Description of Related Art

As the manufacturing technology of semiconductor integrated circuits has been developed, the width of the element formed on a semiconductor substrate has become finer, and the level of integration per unit area has increased.

Meanwhile, as the integration of memory cells increases, the space occupied by the capacitor for storing the charge has become narrower, so the development of the cell capacitor with a high capacitance per unit area is necessary.

In general, the capacitor stores a charge and then supplies the charge required for the operation of the semiconductor device, and as the integration of the semiconductor increases, the size of the cells becomes smaller whereas the capacitance required for the operation of the semiconductor device increases little by little.

As the degree of integration of semiconductor device increases, miniaturization of the capacitor has been required in the conventional art. However, according to the limitation of the charging capacitance, a difficulty in making high integration capacitors in regard to the size of cells has arisen.

Accordingly, to overcome such a problem, in order to increase the amount of charge stored in the capacitor, a material having a high dielectric constant such as TaON has been used to form a dielectric layer.

FIG. 1 is a view illustrating the problem of a capacitor formed by a conventional method of forming a capacitor of a semiconductor device.

As shown in FIG. 1, as the upper electrode is deposited on the dielectric layer at a high temperature, the surface roughness as in “A” of FIG. 1 occurs, which results in reduction of capacitance.

Further, since the upper electrode is made of chemical vapor deposited (CVD) TiN using TiCl₄ as a source, if the thickness of the electrode is greater than 500 Å, the Cl contained in the upper electrode causes a crack on the surface of the upper electrode to increase the leakage of current.

### SUMMARY OF THE DISCLOSURE

The disclosure provides a method for forming a metal (MIS) capacitor of a semiconductor device, in which a TiN layer forming an upper electrode is deposited by an atomic layer deposition (ALD) method using an MO source at low temperature, whereby the crystallization of TiN is minimized to prevent the roughness of the surface, and Cl is not contained in the TiN layer to improve a leakage current characteristic.

More specifically, the disclosure provides a method for forming a capacitor of a semiconductor device, comprising the steps of: forming a nitride layer by a nitriding process or nitric-oxidizing process on a surface of a silicon substrate formed with a lower electrode; forming a dielectric material layer made of a tantalum on the nitride layer, with a chemical vapor; and forming a TiN layer that is an upper electrode, on the dielectric material layer with an ALD method.

The upper electrode is preferably formed by a cycle including a TEMAT vapor pulse or TDMAT vapor pulse, an Ar or N₂ purge, a NH₃ gas pulse, and an Ar or N₂ purge.

### BRIEF DESCRIPTION OF THE DRAWINGS

Other objects and aspects of the method will become apparent from the following description of embodiments with reference to the accompanying drawing in which:

FIG. 1 is a view illustrating the problem of a capacitor formed by conventional methods of forming a capacitor of a semiconductor device; and

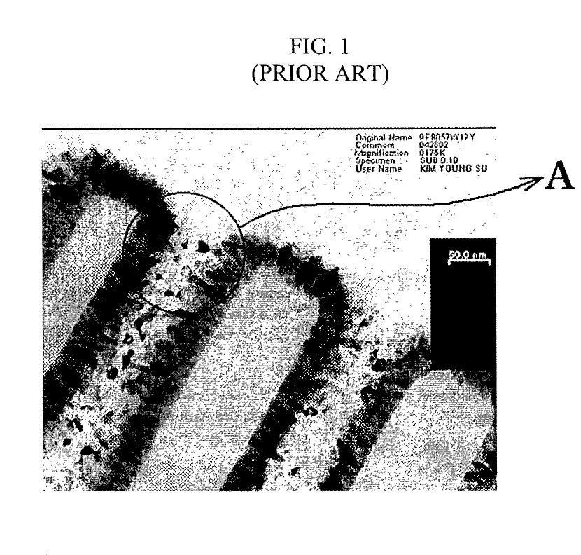

FIGS. 2A through 2C are cross-sectional views illustrating consecutive steps of a method for forming a capacitor of a semiconductor device.

### DESCRIPTION OF THE PREFERRED EMBODIMENT

Hereinafter, a method will be described in more detail with reference to the accompanying drawings.

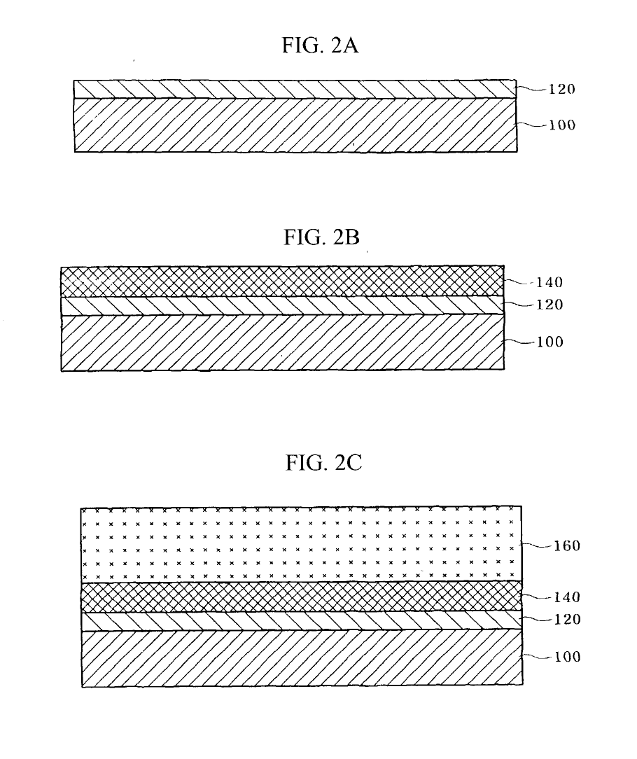

FIGS. 2A through 2C are cross-sectional views for illustrating the consecutive steps of a method for forming a capacitor of a semiconductor device.

As shown in FIG. 2A, a nitride layer 120 is formed by a nitriding process or nitric-oxidizing process on the surface of a silicon substrate 100, using a plasma, a rapid thermal process (RTP), or furnace, so that the forming of a oxide layer of low dielectric constant on an interface is prevented when a dielectric layer which is an amorphous TaON layer is deposited later on the silicon substrate 100 formed with a metallic lower electrode (not shown).

Here, the nitride layer 120 can be formed by performing the nitriding process or the nitric-oxidizing process on the surface of the semiconductor device, by supplying a mixture of NH₃ gas and O₂ gas or NO gas with a rapid thermal process at a temperature of 700° C. to 900° C.

Further, the nitride layer 120 can be formed by performing the nitriding process or the nitric-oxidizing process on the surface of the semiconductor device, by an in-situ process, by using a plasma in an atmosphere of NH₃ gas at a temperature of 300° C. to 600° C., for 30 seconds to 10 minutes.

Next, as shown in FIG. 2B, a dielectric material layer 140 which is an amorphous TaON layer is formed by a surface chemical reaction on the silicon substrate 100 which has undergone the nitride process.

In that situation, the TaON layer is formed by forming a tantalum atomic layer by applying a tantalum hydrofluoride pulse, performing a purge process with nitrogen or argon, forming a nitride atomic layer by applying an ammonia pulse and, consequently, combining the tantalum atoms with the nitride atoms to form a tantalum nitride film (not shown).

Furthermore, the chemical vapor of a tantalum compound such as the tantalum hydrofluoride is formed by supplying a predetermined quantity of the tantalum compound gauged by a quantity controller to an evaporator or an evaporation pipe, and then evaporating the gauged quantity of the tantalum compound at a temperature of 150° C. to 200° C.

Also, the tantalum oxide film is formed by oxidizing the tantalum nitride film (not shown).

In such a situation, a dielectric material layer 140 can be formed using Ta₂O₅ in substitution for TaON, and the uniformity of the dielectric material layer 140 is improved by a thermal treatment at high or low temperature.

Next, as shown in FIG. 2C, a TiN layer that is an upper electrode 160 is formed on the dielectric material layer 140 with an ALD method at a low temperature of 50° C. to 350° C., using an MO source, that is, Ti(N(C2H5CH3)2)4 (TEMAT) and NH3.

In such a situation, Ti(N(CH3)2)4 (TDMAT) can be used as the MO source in substitution for the TEMAT.

Furthermore, the TiN layer that is the upper electrode 160 is formed by a cycle indicating a TEMAT vapor pulse or a TDMAT vapor pulse, an Ar or N₂ purge, an NH₃ gas pulse, and an Ar or N₂ purge, to a thickness of 50 Å to 1600 Å.

However, in case the upper electrode 160 indicates a TiN layer formed by the ALD method and a TiN layer formed by a sputter so as to increase thickness, the TiN layer according to the ALD method is formed having a thickness of 50 Å to 300 Å.

According to the disclosure, a method for forming a metal MIS capacitor of a semiconductor device is provided, in which a TiN layer forming an upper electrode is deposited by an atomic layer deposition (ALD) method using an MO source at low temperature, whereby the crystallization of TiN is minimized to prevent roughness of the surface, and Cl is not contained in the TiN layer to improve the leakage current characteristic.

Although a preferred embodiment of the method has been described, it will be understood by those skilled in the art that the method should not be limited to the described preferred embodiment, but various changes and modifications can be made within the spirit and the scope of the disclosure. Accordingly, the scope of the method is not limited within the described range but the following claims.

What is claimed is:

1. A method for forming a capacitor of a semiconductor device, comprising the steps of:
forming a nitride layer by a nitriding process or a nitric-oxidizing process on a surface of a silicon substrate formed with a lower electrode;
forming a dielectric material layer on the nitride layer using a chemical vapor of a tantalum compound; and
forming a TiN layer that is an upper electrode, on the dielectric material layer with an ALD method.

2. The method of claim 1, comprising forming the upper electrode using TEMAT and NH₃ as a source at low temperature.

3. The method of claim 2, wherein the low temperature is between 50° C. and 350° C.

4. The method of claim 1, comprising forming the upper electrode using TDMAT and NH₃ as a source at low temperature.

5. The method of claim 4, wherein the low temperature is between 50° C. and 350° C.

6. The method of claim 1, comprising forming the upper electrode by a cycle comprising a TEMAT vapor pulse, an Ar or N₂ purge, a NH₃ gas pulse, and an Ar or N₂ purge.

7. The method of claim 1, comprising forming the upper electrode by a cycle comprising a TDMAT vapor pulse, an Ar or N₂ purge, a NH₃ gas pulse, and an Ar or N₂ purge.

8. The method of claim 1, comprising forming the upper electrode with a thickness of 50 Å to 1600 Å.

9. The method of claim 1, comprising forming the upper electrode of a TiN layer by an ALD method and a thick TiN layer by a sputter, the TiN layer formed by the ALD method having a thickness of 50 Å to 300 Å.

10. The method of claim 1, comprising forming the nitride layer by supplying a mixture of NH₃ gas and O₂ or NO gas with a rapid thermal process at a temperature of 700° C. to 900° C.

11. The method of claim 1, comprising forming the nitride layer by an in-situ process, by using a plasma in an atmosphere of NH₃ gas at a temperature of 300° C. to 600° C., for 30 seconds to 10 minutes.
